(19) United States
(12) Patent Application Publication
(10) Pub. No.: US 2025/0185299 A1
(43) Pub. Date: Jun. 5, 2025

(54) ENLARGED BACKSIDE CONTACT THROUGH STI LINER RECESS

(71) Applicant: INTERNATIONAL BUSINESS MACHINES CORPORATION, ARMONK, NY (US)

(72) Inventors: Lijuan Zou, Albany, NY (US); Tao Li, Slingerlands, NY (US); Ruilong Xie, Niskayuna, NY (US); Nicolas Jean Loubet, GUILDERLAND, NY (US)

(21) Appl. No.: 18/529,069

(22) Filed: Dec. 5, 2023

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/013; H10D 84/0149; H10D 84/038; H10D 84/83

(57) ABSTRACT

A microelectronic structure including a first nanosheet transistor that includes a first source/drain and a second nanosheet transistor that includes a second source/drain. The first source/drain and the second source/drain are aligned along a common axis. The common axis is parallel to a gate direction. A backside width of the first source/drain and a backside width of the second source/drain are different as measured along the common axis. A bottom dielectric isolation layer located on a backside surface of the second source/drain. A backside contact located on a backside surface of the first source/drain.

### BACKGROUND

The present invention generally relates to the field of microelectronics, and more particularly to the formation of a wider backside contact by recessing the shallow trench isolation liner.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form separate backside contacts that have enough surface contact with the source/drains.

### BRIEF SUMMARY

Additional aspects and/or advantages will be set forth in part in the description which follows and, in part, will be apparent from the description, or may be learned by practice of the invention.

A microelectronic structure including a first nanosheet transistor that includes a first source/drain and a second nanosheet transistor that includes a second source/drain. The first source/drain and the second source/drain are aligned along a common axis. The common axis is parallel to a gate direction. A backside width of the first source/drain and a backside width of the second source/drain are different as measured along the common axis. A bottom dielectric isolation layer located on a backside surface of the second source/drain. A backside contact located on a backside surface of the first source/drain.

A microelectronic structure that includes a first nanosheet transistor that includes a first source/drain and a second nanosheet transistor that includes a second source/drain. The first source/drain and the second source/drain are aligned along a common axis and the common axis is parallel to a gate direction. A placeholder located on a backside surface of the second source/drain. The placeholder includes a shaft section and a head section and the head section is wider than the shaft section as measured along the common axis. A backside contact located on a backside surface of the first source/drain.

A method that includes the steps of forming alternating layers of sacrificial layers and nanosheet channel layers on a substrate. Separating the alternating layers into a plurality of rows and the separating the alternating layers causes a plurality of trenches to form in the substrate. Lining the trenches with a shallow trench isolation liner and filling the remaining space within the trench with a shallow trench isolation fill layer. Recessing the shallow trench isolation liner to create a sacrificial trench and forming a sacrificial plug in the sacrificial trench.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross section X of the nanosheet transistor after separating the nanostack into columns, formation of the shallow trench isolation liner and the shallow trench isolation fill layer, and the formation of sacrificial plugs, in accordance with the embodiment of the present invention.

FIG. 3 illustrates a cross section Y of the source/drain region after separating the nanostack into columns, formation of the shallow trench isolation liner and the shallow trench isolation fill layer, and the formation of sacrificial plugs, in accordance with the embodiment of the present invention.

FIG. 4 illustrates a cross section X of the nanosheet transistor after formation of a dummy gate, formation of a second hardmask, patterning the dummy gate and the second hardmask into a plurality of columns, formation of a bottom dielectric isolation layer and the formation of the gate spacer, formation of the source/drain regions, and the formation of the inner spacer, in accordance with the embodiment of the present invention.

FIG. 5 illustrates a cross section Y of the source/drain region after formation of a dummy gate, formation of a second hardmask, patterning the dummy gate and the second hardmask into a plurality of columns, formation of a bottom dielectric isolation layer and the formation of the gate spacer, formation of the source/drain regions, and the formation of the inner spacer, in accordance with the embodiment of the present invention.

FIG. 6 illustrates a cross section X of the nanosheet transistor after formation of a sacrificial liner and a first lithography layer and the formation of the placeholder trench, in accordance with the embodiment of the present invention.

FIG. 7 illustrates a cross section Y of the source/drain region after formation of a sacrificial liner and a first lithography layer and the formation of the placeholder trench, in accordance with the embodiment of the present invention.

FIG. 8 illustrates a cross section Y of the source/drain region after formation of a sacrificial liner and a first lithography layer and the formation of a plurality of placeholder trenches, in accordance with the embodiment of the present invention.

FIG. 9 illustrates a cross section X of the nanosheet transistor after the removal of the first lithography layer and the formation of the placeholder, in accordance with the embodiment of the present invention.

FIG. 10 illustrates a cross section Y of the source/drain region after the removal of the first lithography layer and the formation of the placeholder, in accordance with the embodiment of the present invention.

FIG. 11 illustrates a cross section Y of the source/drain region after the removal of the first lithography layer and the formation of a plurality of placeholders, in accordance with the embodiment of the present invention.

FIG. 12 illustrates a cross section X of the nanosheet transistor after the formation of source/drains, in accordance with the embodiment of the present invention.

FIG. 13 illustrates a cross section Y of the source/drain region after the formation of source/drains, in accordance with the embodiment of the present invention.

FIG. 14 illustrates a cross section Y of the source/drain region after the formation of source/drains, in accordance with the embodiment of the present invention.

FIG. 15 illustrates a cross section X of the nanosheet transistor after the formation of a frontside interlayer dielectric layer, removal of the second hardmask, the dummy gate, and the sacrificial layers, the formation of the gate, formation of additional frontside interlayer dielectric layer, formation of frontside contact, formation back-end-of-the-line (BEOL) layers, and the formation of the carrier wafer, in accordance with the embodiment of the present invention.

FIG. 16 illustrates a cross section Y of the source/drain region after the formation of a frontside interlayer dielectric layer, removal of the second hardmask, the dummy gate, and the sacrificial layers, the formation of the gate, formation of additional frontside interlayer dielectric layer, formation of frontside contact, formation back-end-of-the-line (BEOL) layers, and the formation of the carrier wafer, in accordance with the embodiment of the present invention.

FIG. 17 illustrates a cross section X of the nanosheet transistor after flipping the nanosheet transistor over for backside processing and the removal of the first substrate, the etch stop and the second substrate, in accordance with the embodiment of the present invention.

FIG. 18 illustrates a cross section Y of the source/drain region after flipping the nanosheet transistor over for backside processing and the removal of the first substrate, the etch stop and the second substrate, in accordance with the embodiment of the present invention.

FIG. 19 illustrates a cross section X of the nanosheet transistor after formation of the backside interlayer dielectric layer and a planarization process, in accordance with the embodiment of the present invention.

FIG. 20 illustrates a cross section Y of the source/drain region after formation of the backside interlayer dielectric layer and a planarization process, in accordance with the embodiment of the present invention.

FIG. 21 illustrates a cross section X of the nanosheet transistor after recessing the placeholder, in accordance with the embodiment of the present invention.

FIG. 22 illustrates a cross section Y of the source/drain region after recessing the placeholder, in accordance with the embodiment of the present invention.

FIG. 23 illustrates a cross section Y of the source/drain region after selective removal of a portion of the shallow trench isolation liner, in accordance with the embodiment of the present invention.

FIG. 24 illustrates a cross section X of the nanosheet transistor after removal of the placeholder, in accordance with the embodiment of the present invention.

FIG. 25 illustrates a cross section Y of the source/drain region after removal of the placeholder, in accordance with the embodiment of the present invention.

FIG. 26 illustrates a cross section X of the nanosheet transistor after formation of a backside contact and the formation of a backside-power-distribution-network, in accordance with the embodiment of the present invention.

FIG. 27 illustrates a cross section Y of the source/drain region after formation of a backside contact and the formation of a backside-power-distribution-network, in accordance with the embodiment of the present invention.

FIG. 28 illustrates a cross section X of the nanosheet transistor after formation of the backside interlayer dielectric layer, in accordance with the embodiment of the present invention.

FIG. 29 illustrates a cross section Y of the source/drain region after formation of the backside interlayer dielectric layer, in accordance with the embodiment of the present invention.

FIG. 30 illustrates a cross section X of the nanosheet transistor after formation of a contact trench, recessing of the exposed placeholder, and the removal of the exposed shallow trench isolation liner, in accordance with the embodiment of the present invention.

FIG. 31 illustrates a cross section Y of the source/drain region after formation of a contact trench, recessing of the exposed placeholder, and the removal of the exposed shallow trench isolation liner, in accordance with the embodiment of the present invention.

FIG. 32 illustrates a cross section X of the nanosheet transistor after formation of a backside contact and the formation of a backside-power-distribution-network, in accordance with the embodiment of the present invention.

FIG. 33 illustrates a cross section Y of the source/drain region after formation of a backside contact and the formation of a backside-power-distribution-network, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “top,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards the formation of a wider source/drain and a wider backside contact by increasing the width of the placeholder. After separating the nano stack (e.g., the alternating layers of channel layers and sacrificial layers) into a plurality of rows/columns for the formation of different transistors. Trenches are formed in the underlying substrate during the separation of the alternating layers and these trenches are filled with a shallow trench isolation (STI) liner and a STI fill layer. The STI liner is pulled down at the location where a placeholder will be formed to create recesses/valleys and these recess/valleys are filled with a sacrificial plug. A placeholder trench is etched in the source/drain region between sacrificial plug segments. The sacrificial plugs are removed to increase the lateral/width dimension of the placeholder trench. The removal of the sacrificial plugs gives the placeholder trench a T-shaped profile as viewed from a cross section of the source/drain region parallel to the gate direction. The placeholder trench extends over a portion of the STI liner and exposes a side section of the STI fill layer. The wider placeholders allow for a wider epitaxially growth of the source/drain. In the situation where placeholders are strategically placed (i.e., not located everywhere) will cause a difference in width dimensions of the source/drains grown on placeholders and source/drain that are not grown on placeholders. In the situation where placeholders are placed under each of the source/drain regions, then an inverted T-shape placeholder will be located on the backside of the source/drains where the placeholder are not removed.

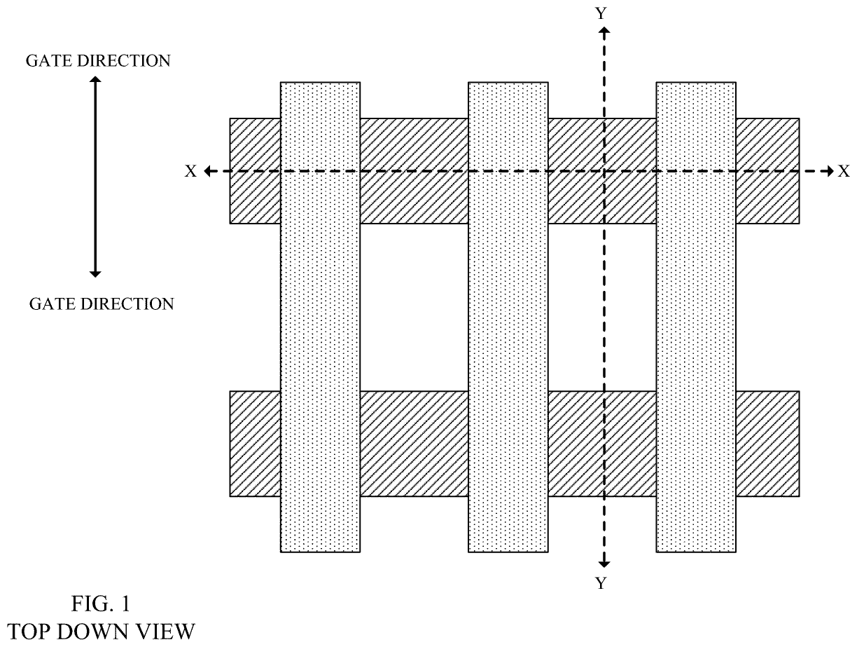

FIG. 1 illustrates a top-down view of multiple devices, in accordance with the embodiment of the present invention. The cross-section X extends horizontally through nanosheet transistors. Cross section Y is perpendicular to cross section X, where cross section Y is through a source/drain region that spans across multiple adjacent nanosheet transistors. Cross-section X is perpendicular to the gate direction and cross-section Y is parallel to the gate direction.

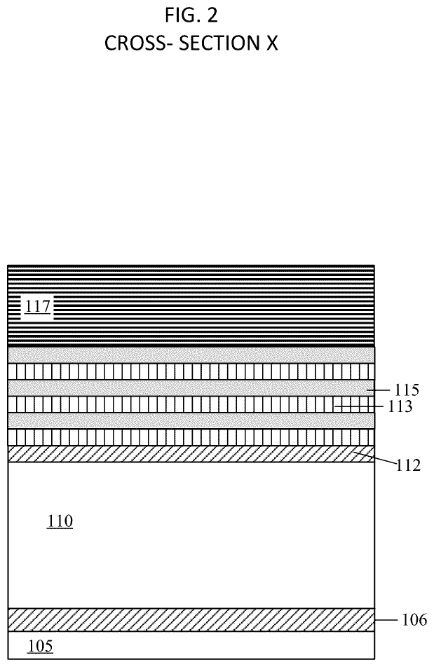

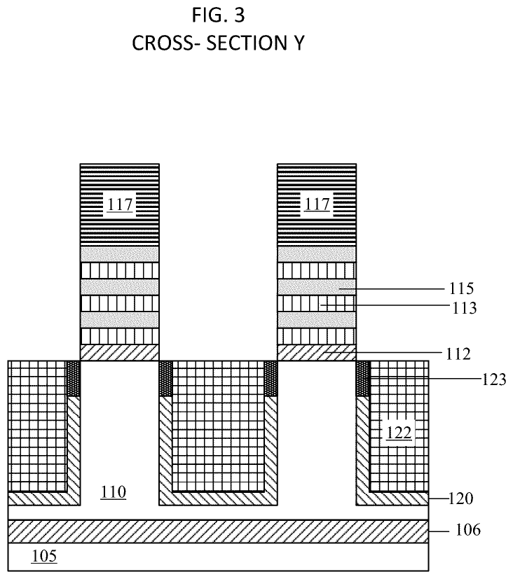

Referring now to FIGS. 2 and 3, a structure is shown during an intermediate step of a method of fabricating stacked nano devices, such as, a stacked nanosheet transistor structure after separating the nanostack into nanostack columns, formation of the shallow trench isolation liner and the shallow trench isolation fill layer, and the formation of sacrificial plugs, according to an embodiment of the invention.

FIGS. 2 and 3 illustrate the processing stage after separating the nanostack into nanostack columns, formation of the shallow trench isolation (STI) liner 120 and the shallow trench isolation (STI) fill layer 122, and the formation of sacrificial plugs 123.

FIG. 2 illustrates the nano stack of the nanosheet transistors that includes a first substrate 105, an etch stop 106, a second substrate 110, a first sacrificial layer 112, a nanostack, and a first hardmask 117. The nanostack is comprised of a plurality of alternating layers that include channel layers 115, and sacrificial layers 113. The plurality of channel layers 115 can be comprised of, for example, Si. The plurality of sacrificial layers 113 can be comprised of SiGe, where Ge is in the percentage of 15 to 35%.

The first substrate 105 and the second substrate 110 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of the first substrate 105 and the second substrate 110. In some embodiments, first substrate 105 and the second substrate 110 includes both semiconductor materials and dielectric materials. The semiconductor first substrate 105 and the second substrate 110 may also comprise an organic semiconductor or a layered semiconductor such as, for example, Si/SiGe, a silicon-on-insulator or a SiGe-on-insulator. A portion or the entire semiconductor first substrate 105 and the second substrate 110 may also be comprised of an amorphous, polycrystalline, or monocrystalline. The semiconductor first substrate 105 and the second substrate 110 may be doped, undoped or contain doped regions and undoped regions therein.

The first hardmask 117 is located on top of the nanostack. The nanostack and the first hardmask are patterned/etched to separate the nanostack into a plurality of columns/rows. The etching/patterning process causes trenches (not shown) to be formed in the second substrate 110. The trenches are located between adjacent nanostack columns/rows. As illustrated in FIG. 3, these trenches are filled with a STI liner 120 and a STI fill layer 122. The STI liner 120 is located between the second substrate 110 and the STI fill layer 122. The STI liner 120 located adjacent to the nanostack columns is pulled down/etched to create trench/recess/valley (not shown) located adjacent to the nanostack columns. These trenches/recesses/valleys are filled with a sacrificial material to form sacrificial plugs 123. The sacrificial material of the sacrificial plugs 123 can be comprised of a dielectric material, for example, SiC, SiOC, or another suitable material. The sacrificial plugs 123 are comprised of a different material than the STI liner 120, thus allowing for the selective etching of the sacrificial plugs 123.

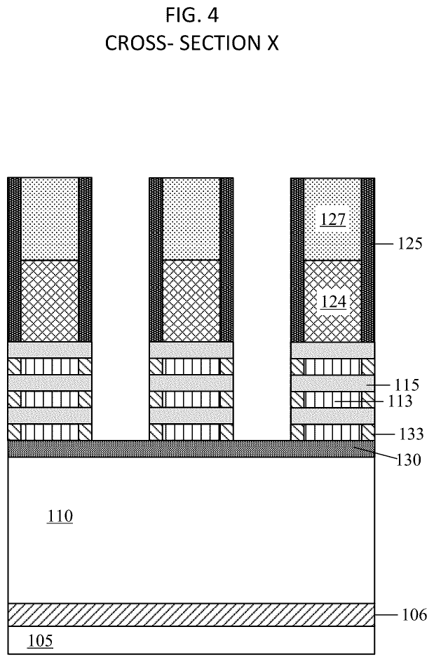

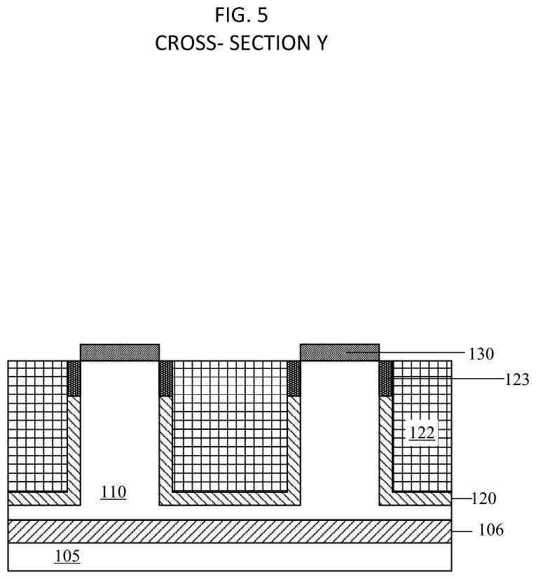

FIGS. 4 and 5 illustrate the processing stage after formation of a dummy gate 124, formation of a second hardmask 127, patterning the dummy gate 124 and the second hardmask 127 into a plurality of columns, formation of a bottom dielectric isolation layer 130 and the formation of the gate spacer 125, formation of the source/drain regions, and the formation of the inner spacer 133.

A dummy gate 124 is formed on top of the nanostacks, the STI layer 122, and the sacrificial plugs 123. A second hardmask 127 is formed on top of the dummy gate 124. The dummy gate 124 and the second hardmask 127 are patterned to form a plurality of columns on top of the nanostack. The first sacrificial layer 112 is selectively removed and a bottom dielectric isolation layer 130 is formed in the location of the removed first sacrificial layer 112. Gate spacer 125 is formed on the exposed surfaces and patterned such that the gate spacer 125 is located adjacent the columns comprised of the dummy gate 124 and the second hardmask 127. The nanostack is patterned/etch to form the source/drain region located between columns of the remaining nanostack. FIG. 5 illustrates the source/drain region and FIG. 4 illustrates that the source/drain region is located between columns of the nanostack. The sacrificial layers 113 are recessed to create space around the channel layers 115. Inner spacer 133 is formed by filling the space made available by the recessing of the sacrificial layers 113.

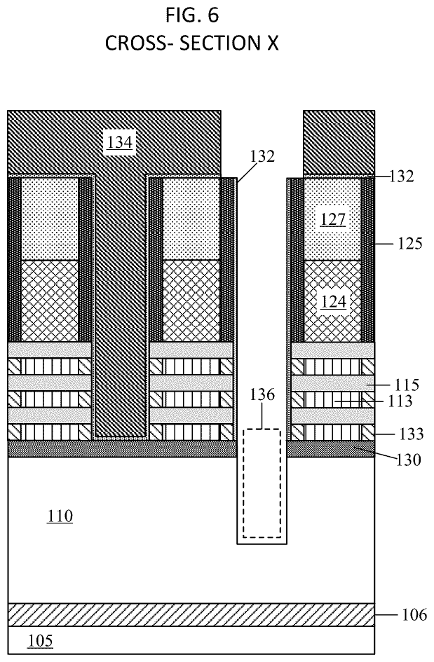

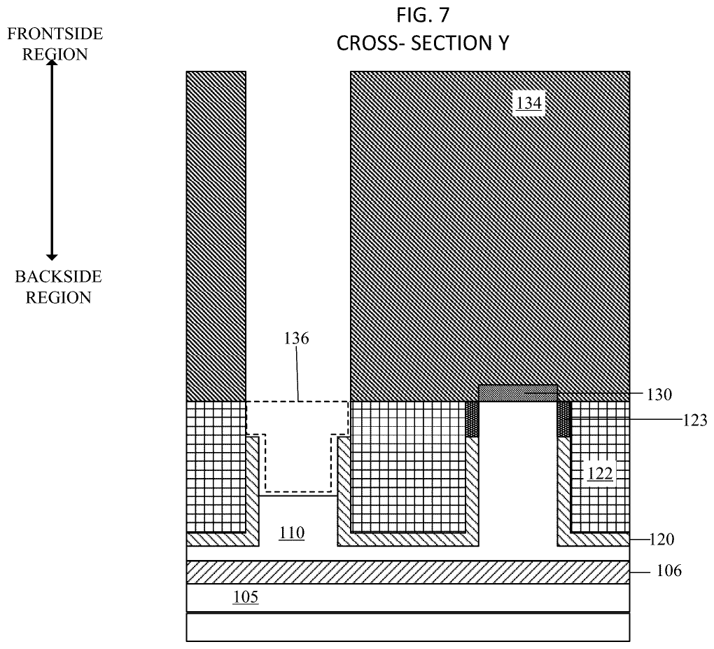

FIGS. 6 and 7 illustrate the processing stage after formation of a sacrificial liner 132 and a first lithography layer 134 and the formation of the placeholder trench 136. A sacrificial liner 132 is formed on the exposed surfaces and a first lithography layer 134 is formed on top of the sacrificial liner 132. The first lithography layer 134 and the sacrificial liner 132 are patterned to form at least one placeholder trench 136 in one of the source/drain regions. The placeholder trench 136 extends through the bottom dielectric isolation layer 130 and into the second substrate 110. As illustrated in FIG. 7, the placeholder trench 136 extends downwards (towards the backside region) between two sections of the STI liner 120. The sacrificial plugs 123 exposed by the placeholder trench 136 are removed to increase the lateral dimensions of the placeholder trench 136. The removal of the sacrificial plugs 123 gives the placeholder trench 136 a T-shaped profile as viewed from a cross-section parallel to the gate direction through the source/drain region. Placeholder trench 136 extends over a top surface of the STI liner 120 and exposes a portion of the sidewall of the STI fill layer 122.

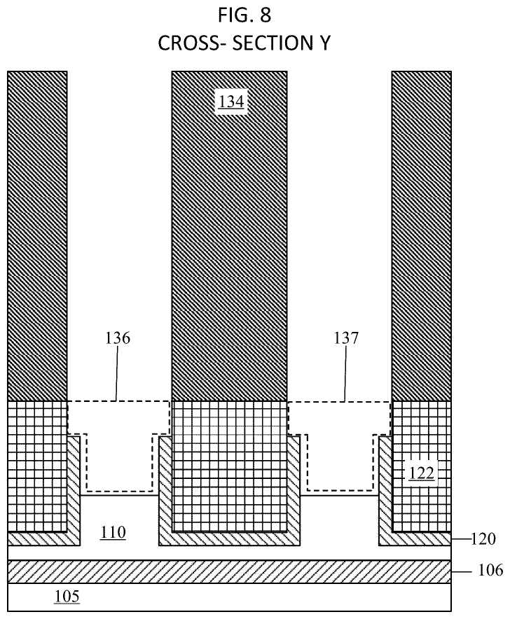

FIG. 8 illustrates the processing stage after formation of a sacrificial liner 132 and a first lithography layer 134 and the formation of a plurality of placeholder trenches 136, 137. FIG. 8 is similar to FIG. 7, but instead of forming a single placeholder trench 136 in one of the source/drain regions a plurality of placeholder trenches 136, and 137 are formed. Where each of the plurality of placeholder trenches 136, 137 are formed in different source/drain regions located between different nanostack columns. Each of the placeholder trenches 136, 137 has the T-shaped profile as viewed from a cross-section parallel to the gate direction through the source/drain region since the sacrificial plugs 123 were removed.

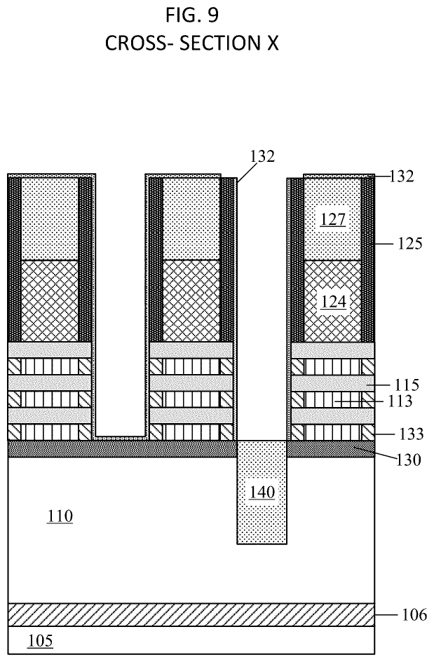

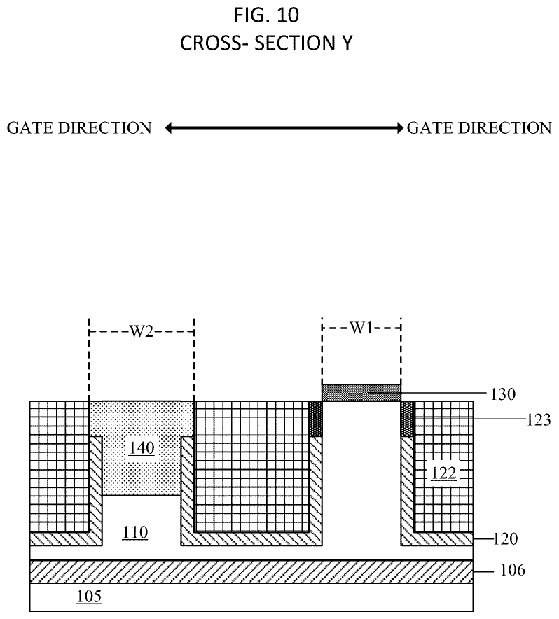

FIGS. 9 and 10 illustrate the processing stage after the removal of the first lithography layer 134 and the formation of the placeholder 140. The first lithography layer 134 is removed and the placeholder trench 136 is filled in to form placeholder 140. Placeholder 140 is epitaxially grown within the placeholder trench 136. As seen in FIG. 10, placeholder 140 has a T-shape profile as viewed from a cross-section parallel to the gate direction through the source/drain region. The bottom dielectric isolation layer 130 has a first width W1 as measured in parallel to the gate direction. Placeholder 140 is comprised of a top section and a shaft section, where the top section is wider than the shaft section. The top section of placeholder 140 has a second width W2 as measured in parallel to the gate direction. The second width W2 is larger than the first width W1.

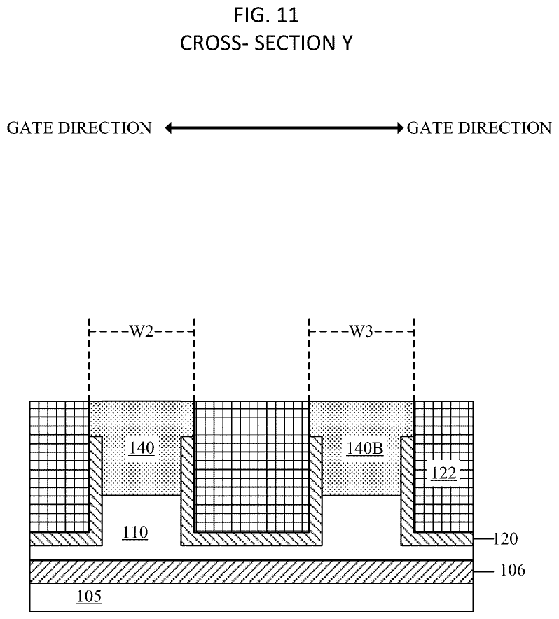

FIG. 11 illustrates the processing stage after the removal of the first lithography layer 134 and the formation of a plurality of placeholders 140, 140B. FIG. 11 illustrates the continued processing of the plurality of placeholder trenches 136, 137 illustrated in FIG. 8. The first lithography layer 134 is removed and the placeholder trench 136, 137 is filled in to form a plurality of placeholders 140, 140B. Placeholders 140, 140B are epitaxially grown within the placeholder trench 136 and epitaxially growing placeholder 140B within placeholder trench 137. Each of the plurality of placeholders 140, 140B is comprised of a top section and a shaft section, where the top section is wider than the shaft section. The top section of placeholder 140 has a second width W2 as measured in parallel to the gate direction. The top section of placeholder 140B has a third width W3 as measured in parallel to the gate direction. The second width W2 and the third width W3 are substantially equal to each other.

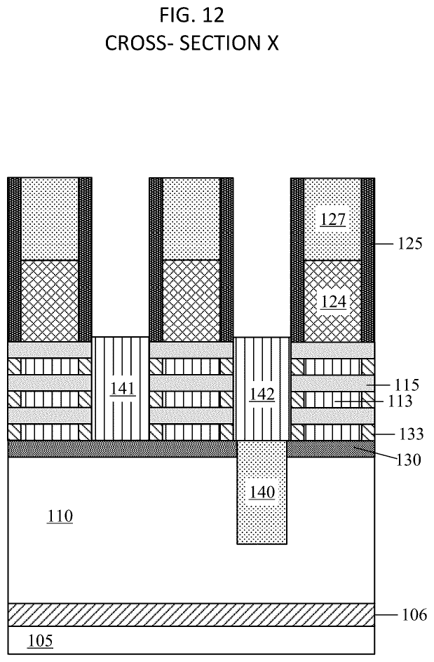

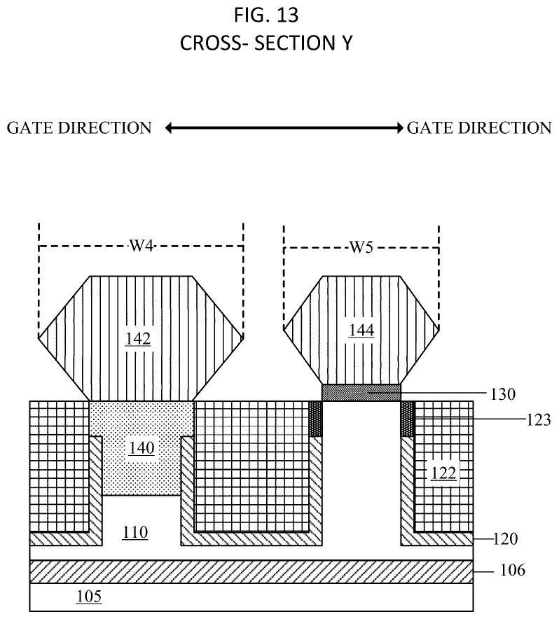

FIGS. 12 and 13 illustrate the processing stage after the formation of source/drains 141, 142, 144. The source/drain 141, 142, 144 are epitaxially grown in the source/drain regions. The first source/drain 141 is epitaxially grown on bottom dielectric isolation layer 130 located in the source/drain region located between two adjacent nanostacks as illustrated in FIG. 12. The second source/drain 142 is epitaxially grown on top of the placeholder 140 as illustrated in FIGS. 12 and 13. The second source/drain 142 has a fourth width W4 as measured in parallel to the gate direction. A third source/drain 144 is epitaxially grown on bottom dielectric isolation layer 130 located in the source/drain region adjacent to the second source/drain 142. The third source/drain 142 has a fifth width W5 as measured in parallel to the gate direction. The fourth width W4 of the second source/drain 142 is larger than the fifth width W5 of the third source/drain 144. The second source/drain 142 has a larger width because of the larger width of the placeholder 140 (width W2) when compared to the smaller width W5 of the third source/drain 144. The third source/drain 144 has a smaller width W5 because of the smaller width (width W1) of the bottom dielectric isolation layer 130 that served as the based for the third source/drain 144.

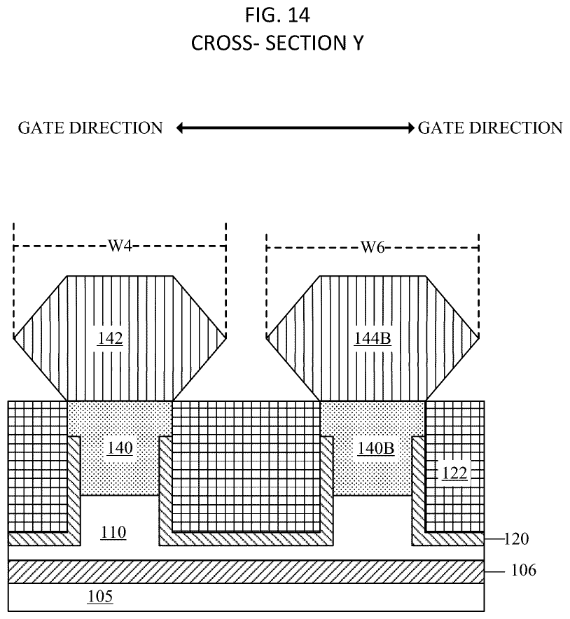

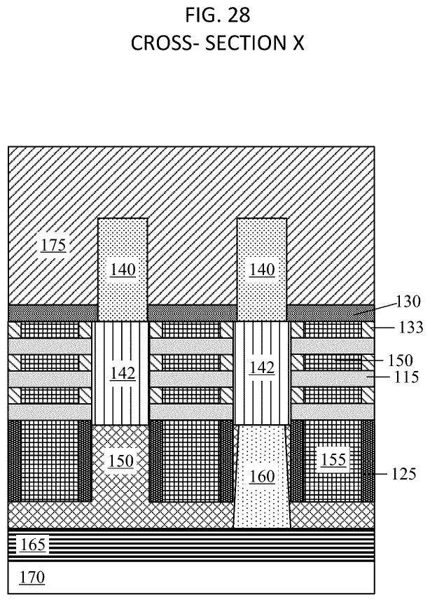

FIG. 14 illustrates the processing stage after the formation of source/drains 142, 144B on the plurality of placeholders 140, 140B. FIG. 14 is similar to FIGS. 12 and 13, instead of the source/drains 141, 144 being formed on top of the bottom dielectric layer 130, instead these source/drains 142, 144B are formed on top of placeholders 140, 140B. FIG. 28, which will be described in further detail below illustrates cross-section X, illustrates a plurality of placeholders 140 are formed and a source/drain 142 is formed on top of each of the plurality of placeholders 140. FIG. 14 illustrates the two source/drain regions that are laterally aligned along a common axis parallel to the gate direction. The fourth source/drain 144B is epitaxially grown on top of the placeholder 140B. The fourth source/drain 144B has a sixth width W6 as measured in parallel to the gate direction. The fifth width W5 is substantially equal to the sixth width W6.

The first, second, third, or fourth source/drains 141, 142, 144, 144B can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

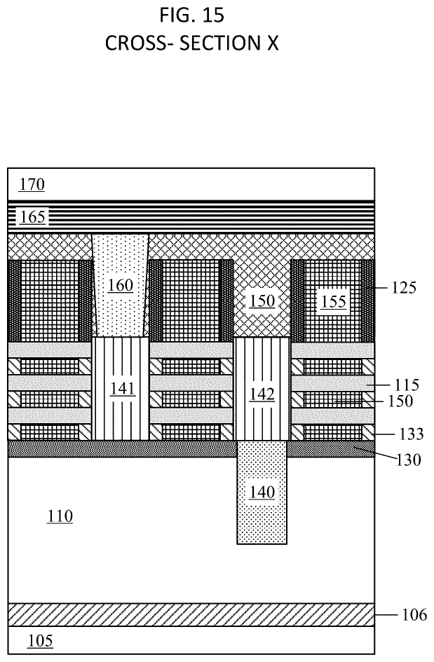

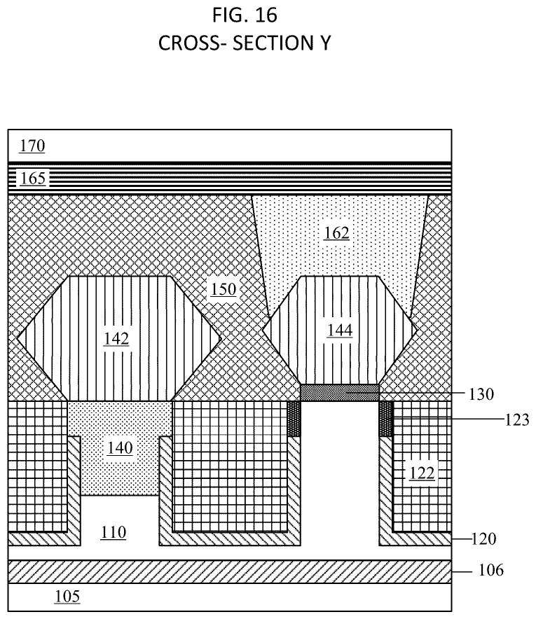

FIGS. 15 and 16 illustrate the processing stage after the formation of a frontside interlayer dielectric layer 150, removal of the second hardmask 127, the dummy gate 124, and the sacrificial layers 113, the formation of the gate 155, formation of additional frontside interlayer dielectric layer 150, formation of frontside contact 160, 162, formation back-end-of-the-line (BEOL) layers 165, and the formation of the carrier wafer 170.

A frontside interlayer dielectric layer 150 is formed on top and around the source/drains 141, 142, and 144. The second hardmask 127, dummy gate 124, and the sacrificial layers 113 are removed to create space for the formation of gate 155. Gate 155 is formed in the locations of the removed dummy gate 124 and the sacrificial layers 113. Gate 155 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

Additional frontside interlayer dielectric layer 150 material is added to extend the frontside interlayer dielectric layer 150 on top of gate 155. A plurality of trenches (not shown) are formed in the frontside interlayer dielectric layer 150 and filled with a conductive metal to form a first frontside contact 160 and a second frontside contact 162. BEOL layer 165 is formed on top of the first frontside contact 160, on top of the second frontside contact 162, and on top of the frontside interlayer dielectric layer 150. Carrier wafer 170 is formed on top of the BEOL layer 165.

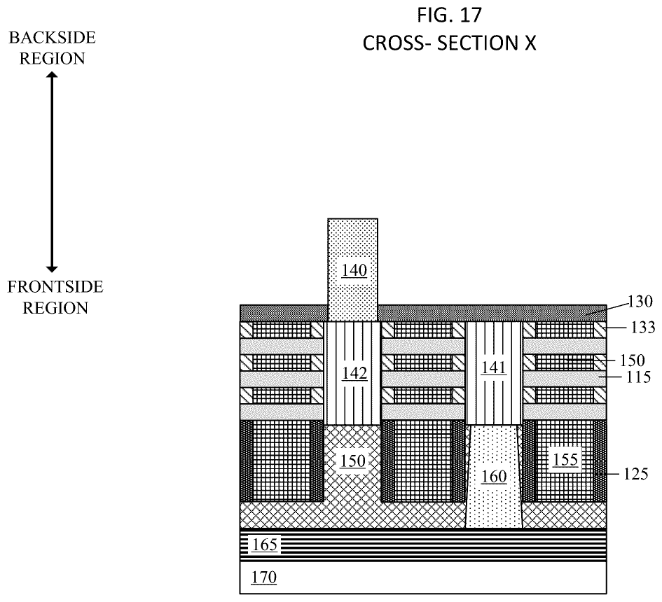

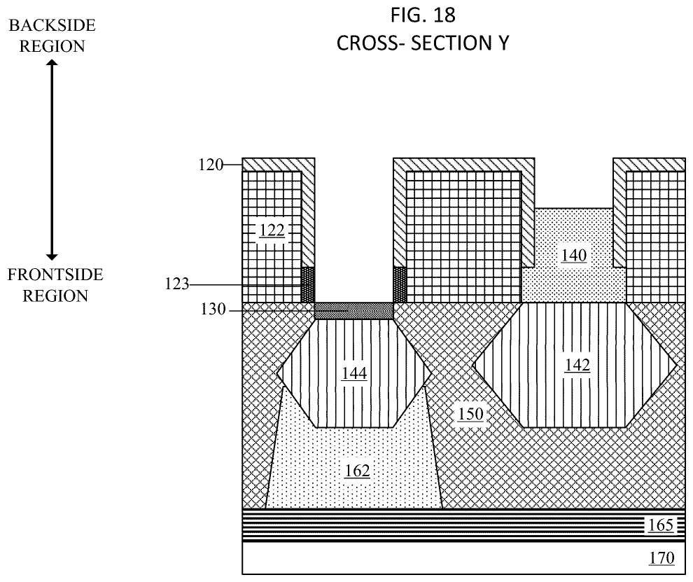

FIGS. 17 and 18 illustrate the processing stage after flipping the nanosheet transistor over for backside processing and the removal of the first substrate 105, the etch stop 106 and the second substrate 110. FIGS. 2-16 illustrate the frontside processing of the nanosheet transistor and FIGS. 17-33 illustrate the backside processing of the nanosheet transistor. Carrier wafer 170 allows for the flipping of the nanosheet transistor to expose the backside region. The first substrate 105, the etch stop 106, and the second substrate 110 are removed. The removal of these layers causes placeholder 140 and the backside surface of the bottom dielectric isolation layer 130 to be exposed. Furthermore, the removal of the second substrate 110 exposes the STI liner 120 and the sacrificial plugs 123, as illustrated in FIG. 18.

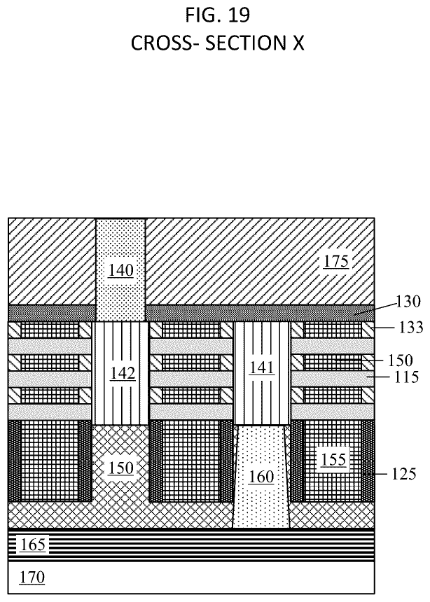

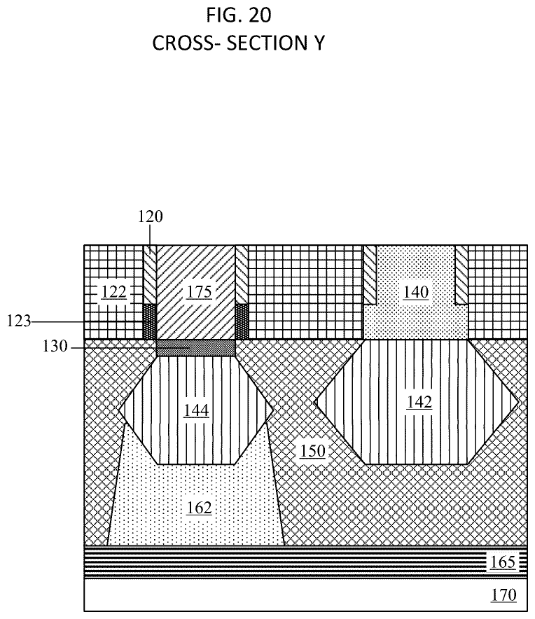

FIGS. 19 and 20 illustrate the processing stage after formation of the backside interlayer dielectric layer 175 and a planarization process. Backside interlayer dielectric layer 175 is formed on top of the backside surface of the bottom dielectric isolation layer 130 and around the placeholder 140. Furthermore, the backside interlayer dielectric layer 175 is formed on the backside region of the third source/drain 144, such that the backside interlayer dielectric layer 175 is in contact with the STI liner 120 and the sacrificial plugs 123. A planarization process, for example, chemical mechanical processing (CMP), is utilized to lower the height of the STI fill layer 122, the STI liner 120, and the height of the backside interlayer dielectric layer 175. The planarization process forms a uniform/flat surface across the STI fill layer 122, the STI liner 120, the backside interlayer dielectric layer 175, and the placeholder 140.

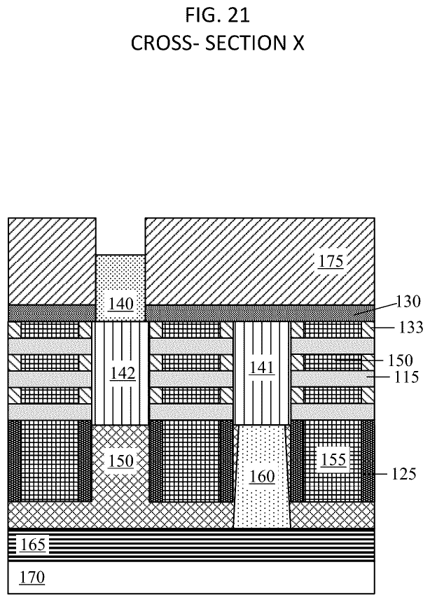

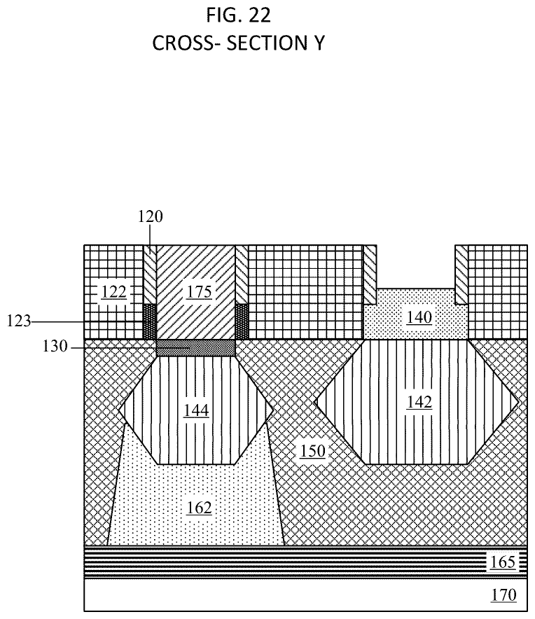

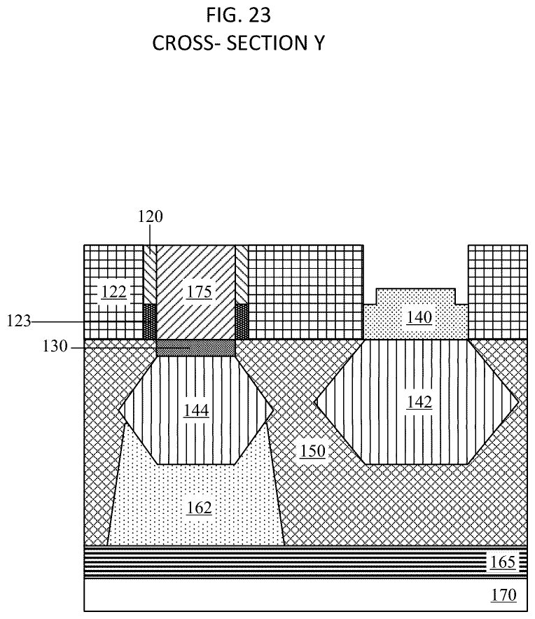

FIGS. 21 and 22 illustrate the processing stage after recessing the placeholder 140. The placeholder 140 is partially recessed/pulled down to create a valley/trench above the placeholder 140, thus exposing the side surfaces of the STI liner 120. The side boundaries of the trench are formed by the STI liner 120. FIG. 23 illustrates the processing stage after the selective removal of a portion of the STI liner 120. The STI liner 120 exposed by the recessing of the placeholder 140 is selectively removed. The STI liner 120 located adjacent to the backside interlayer dielectric layer 175, (e.g., the location where a placeholder 140 was not formed) is not removed. The removal of the STI liner 120 widens the trench above the placeholder 140 which will allow for a wider backside contact 180 to be formed, which will be described in further detail below.

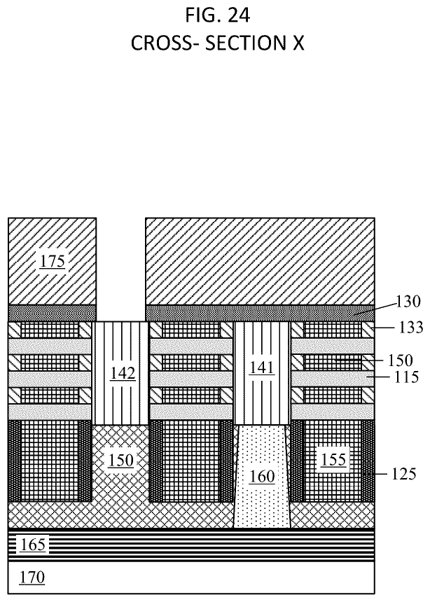

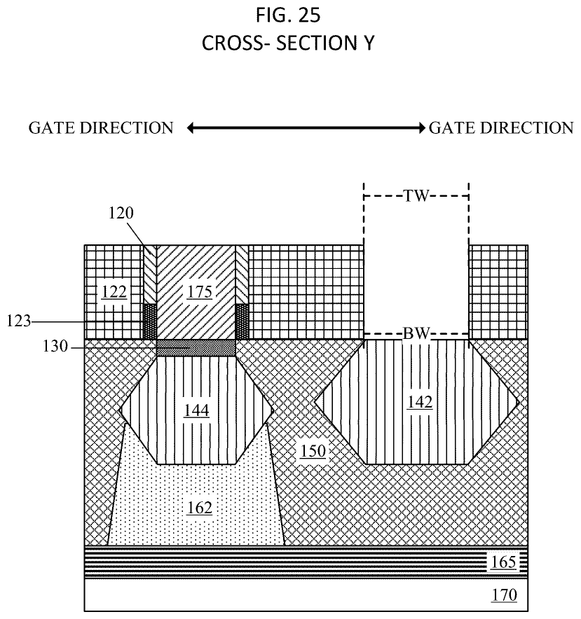

FIGS. 24 and 25 illustrate the processing stage after removal of placeholder 140. Placeholder 140 is removed to expose the backside surface of the second source/drain 142. A trench is created between sections of the STI filler layer 122 and the backside surface of the second source/drain 142. The trench has a bottom width BW (e.g., the part of the trench located directly adjacent to the second source/drain 142), where the bottom width BW is equal to the second width W2 of the top section of the placeholder 140. The trench has a top width TW that is located at the opening of the trench. The top width TW can be greater than or equal to the bottom width BW.

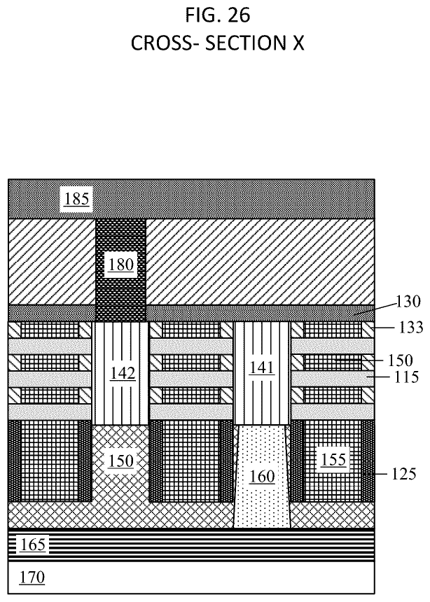

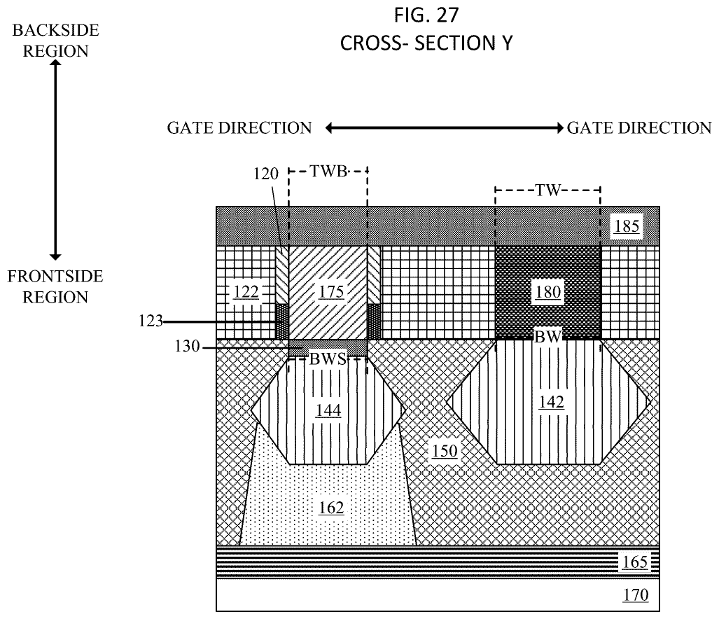

FIGS. 26 and 27 illustrate the processing stage after formation of a backside contact 180 and the formation of a backside-power-distribution-network 185. The trench is filled with a conductive metal to form a backside contact 180 that is in contact with the backside surface of the second source/drain 142. Backside contact 180 has a bottom width BW that is equal to the bottom width BW of the trench and a top width TW that is equal to the top width TW of the trench. The backside interlayer dielectric layer 175 located between sections of the STI liner 120 has a top width TWB as illustrated in FIG. 27. The top width TWB of the backside interlayer dielectric layer 175 is smaller than the top width TW of the backside contact 180. The bottom width BW of the backside contact 180 is equal to the backside width of the second source/drain 142. The backside width BWS of the third source/drain 144 is substantially equal to the first width W1 of the bottom dielectric isolation layer 130. The backside width BW of the second source/drain 142 is greater than the backside width BWS of the third source/drain 144. A backside-power-distribution-network 185 is formed on top of the backside interlayer dielectric layer 175, the STI liner 120, the STI fill layer 122, and the backside contact 180.

A microelectronic structure including a first nanosheet transistor that includes a first source/drain 142 and a second nanosheet transistor that includes a second source/drain 144. The first source/drain 142 and the second source/drain 144 are aligned along a common axis. The common axis is parallel to a gate direction. A backside width BW of the first source/drain 142 and a backside width BWS of the second source/drain 144 are different as measured along the common axis. A bottom dielectric isolation layer 130 located on a backside surface of the second source/drain 144. A backside contact 180 located on a backside surface of the first source/drain 142.

A backside interlayer dielectric layer 175 located on a backside surface of the bottom dielectric layer 130. A shallow trench isolation liner 120 located along a sidewall of the backside interlayer dielectric layer 175. A sacrificial plug 123 located along the sidewall of the backside interlayer dielectric layer 175. The shallow trench isolation liner 120 and the sacrificial plug 123 are vertically aligned along the sidewall of the backside interlayer dielectric layer 175. A frontside interlayer dielectric layer 150 located around the first source/drain 142 and the second source/drain 144. The sacrificial plug 123 is located adjacent to the frontside interlayer dielectric layer 150.

A shallow trench isolation fill layer 122 located adjacent to and in direct contact with a sidewall of the backside contact 180. The sacrificial plug 123 and the shallow trench isolation liner 120 are located between the shallow trench isolation fill layer 122 and the backside interlayer dielectric layer 175. The backside width BW of the first source/drain 142 is greater than the backside width BWS of the second source/drain 144 as measured along the common axis.

A method that includes the steps of forming alternating layers of sacrificial layers 113 and nanosheet channel layers 115 on a substrate 110. Separating the alternating layers into a plurality of rows and the separating the alternating layers causes a plurality of trenches to form in the substrate 110. Lining the trenches with a shallow trench isolation liner 120 and filling the remaining space within the trench with a shallow trench isolation fill layer 122. Recessing the shallow trench isolation liner 120 to create a sacrificial trench and forming a sacrificial plug 123 in the sacrificial trench.

Forming a source/drain region and forming a placeholder shaft trench 136, 137 between sections of the shallow trench isolation liner (see for example, FIG. 8) and the sacrificial plug 123 is aligned with the shallow trench isolation liner 120. Forming the head section of the placeholder trench 136, 137 by removing the sacrificial plug 123.

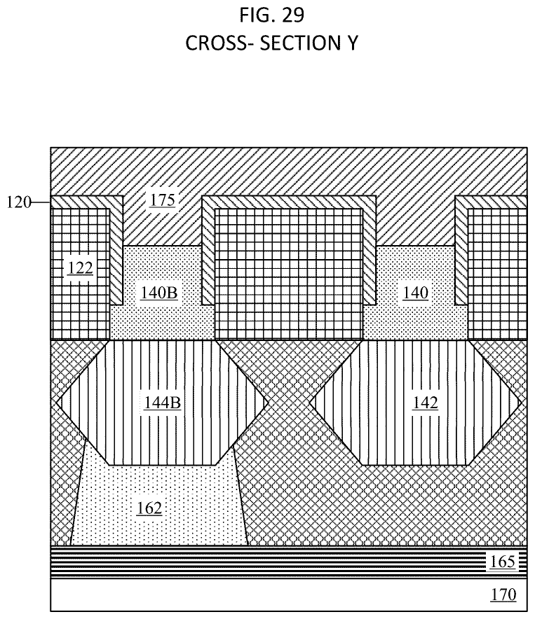

FIGS. 28 and 29 illustrate the processing stage after formation of the backside interlayer dielectric layer 175 in the situation where a plurality of placeholders 140, 140B were formed (as illustrated above in FIG. 14). FIG. 28 illustrates cross-section X through the plurality of nanosheet transistor where a plurality of placeholders 140 were formed. Backside interlayer dielectric layer 175 is formed on top of the exposed backside surface of the bottom dielectric isolation layer 130 and around each of the plurality of placeholders 140. In contrast to what is shown in FIG. 20 a planarization process is not utilized to form a flat surface with the placeholders 140. This process is not utilized because it would expose placeholders that will not be removed. Therefore, the backside interlayer dielectric layer 175 remains on top of the STI liner 120 and on top of the placeholders 140, 140B, as illustrated in FIG. 29.

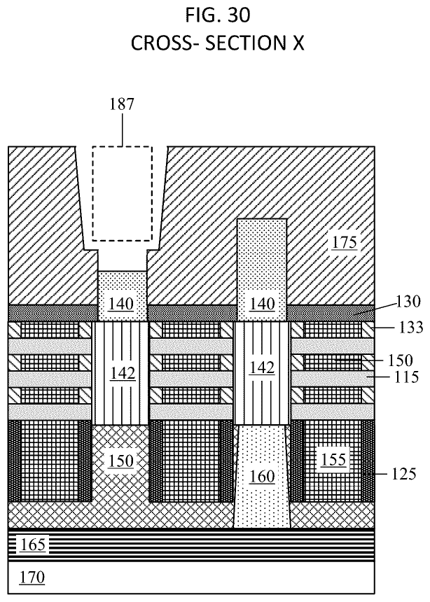

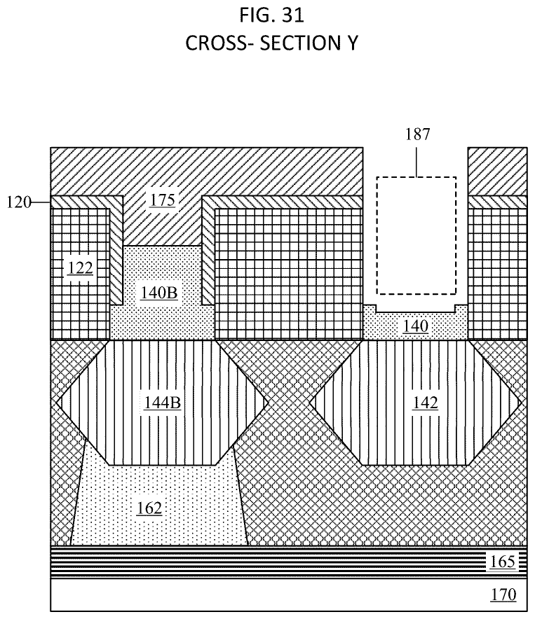

FIGS. 30 and 31 illustrate the processing stage after formation of a contact trench 187, recessing of the exposed placeholder 140, and the removal of the exposed shallow trench isolation liner 120. A lithography layer (not shown) is formed on the backside interlayer dielectric layer 175 and contact trench 187 is formed by patterning the lithography layer and the backside interlayer dielectric layer 175. Contact trench 187 is formed in the backside interlayer dielectric layer 175 which exposes the backside surface of placeholder 140 and exposes a portion of the STI liner 120. Placeholder 140 is recessed to fully expose the STI liner 120 within the contact trench 187. Contact trench 187 is widened by selectively removing the exposed STI liner 120 within the contact trench 187.

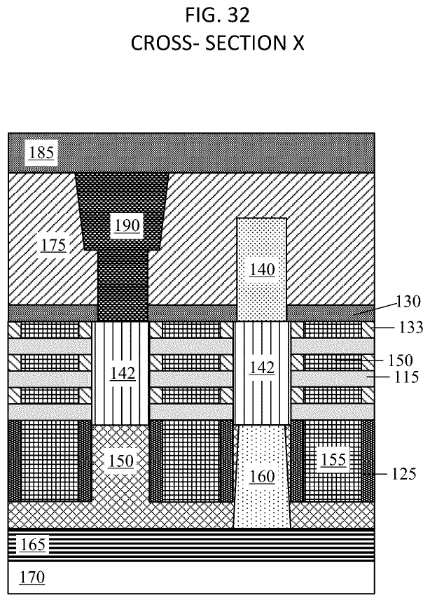

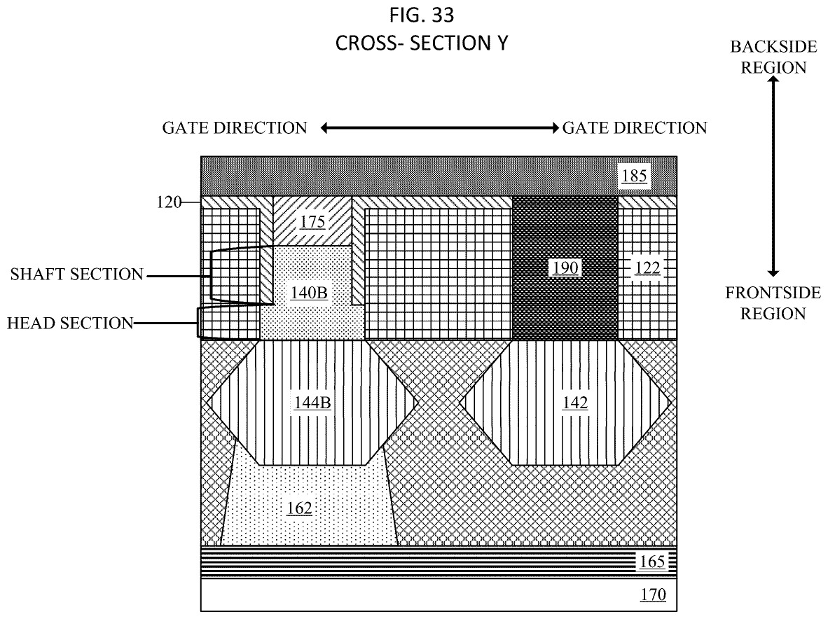

FIGS. 32 and 33 illustrate the processing stage after formation of a backside contact 180 and the formation of a backside-power-distribution-network 185. Placeholder 140 is removed and the contact trench 187 is filled with a conductive metal to form a backside contact 190 that is in contact with the backside surface of the second source/drain 142. A backside-power-distribution network 185 is formed on top of the backside interlayer dielectric layer 175, the STI liner 120, the STI fill layer 122, and the backside contact 180.

A microelectronic structure that includes a first nanosheet transistor that includes a first source/drain 142 and a second nanosheet transistor that includes a second source/drain 144B. The first source/drain 142 and the second source/drain 144B are aligned along a common axis and the common axis is parallel to a gate direction. A placeholder 140B located on a backside surface of the second source/drain 144B. The placeholder 140B includes a shaft section and a head section and the head section is wider than the shaft section as measured along the common axis. A backside contact 190 located on a backside surface of the first source/drain 142.

A backside interlayer dielectric layer 175 located on a backside surface of the shaft section of the placeholder 140B. A shallow trench isolation liner 120 located along a sidewall of the backside interlayer dielectric layer 175 and located along a sidewall of the shaft section of the placeholder 140B. The shallow trench isolation liner 120 is in direct contact with a backside surface of the head section of the placeholder 140B. A shallow trench isolation fill layer 122 located adjacent to and in direct contact with a sidewall of the backside contact 190. The shallow trench isolation liner 120 is located between the shaft section of the placeholder 140B and the shallow trench isolation fill layer 122. A sidewall of the head section of the placeholder 140B is in contact with the shallow trench isolation fill layer 122. The head section and the shaft section of the placeholder gives the placeholder 140B a bolt shaped (or an inverted T-shape) profile as viewed along the common axis.

A method that includes the steps of forming alternating layers of sacrificial layers 113 and nanosheet channel layers 115 on a substrate 110. Separating the alternating layers into a plurality of rows and the separating the alternating layers causes a plurality of trenches to form in the substrate 110. Lining the trenches with a shallow trench isolation liner 120 and filling the remaining space within the trench with a shallow trench isolation fill layer 122. Recessing the shallow trench isolation liner 120 to create a sacrificial trench and forming a sacrificial plug 123 in the sacrificial trench.

Forming a source/drain region and forming a placeholder shaft trench 136, 137 between sections of the shallow trench isolation liner (see for example, FIG. 8) and the sacrificial plug 123 is aligned with the shallow trench isolation liner 120. Forming the head section of the placeholder trench 136, 137 by removing the sacrificial plug 123.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nanosheet transistor that includes a first source/drain;
a second nanosheet transistor that includes a second source/drain, wherein the first source/drain and the second source/drain are aligned along a common axis, wherein the common axis is parallel to a gate direction, wherein a backside width of the first source/drain and a backside width of the second source/drain are different as measured along the common axis;
a bottom dielectric isolation layer located on a backside surface of the second source/drain; and
a backside contact located on a backside surface of the first source/drain.

2. The microelectronic structure of claim 1, further comprising:
a backside interlayer dielectric layer located on a backside surface of the bottom dielectric layer.

3. The microelectronic structure of claim 2, further comprising:
a shallow trench isolation liner located along a sidewall of the backside interlayer dielectric layer; and
a sacrificial plug located along the sidewall of the backside interlayer dielectric layer.

4. The microelectronic structure of claim 3, wherein the shallow trench isolation liner and the sacrificial plug are vertically aligned along the sidewall of the backside interlayer dielectric layer.

5. The microelectronic structure of claim 4, further comprising:
a frontside interlayer dielectric layer located around the first source/drain and the second source/drain.

6. The microelectronic structure of claim 5, wherein the sacrificial plug is located adjacent to the frontside interlayer dielectric layer.

7. The microelectronic structure of claim 6, further comprising:
a shallow trench isolation fill layer located adjacent to and in direct contact with a sidewall of the backside contact.

8. The microelectronic structure of claim 7, wherein the sacrificial plug and the shallow trench isolation liner are located between the shallow trench isolation fill layer and the backside interlayer dielectric layer.

9. The microelectronic structure of claim 1, wherein the backside width of the first source/drain is greater than the backside width of the second source/drain as measured along the common axis.

10. A microelectronic structure comprising:
a first nanosheet transistor that includes a first source/drain;
a second nanosheet transistor that includes a second source/drain, wherein the first source/drain and the second source/drain are aligned along a common axis, wherein the common axis is parallel to a gate direction;
a placeholder located on a backside surface of the second source/drain, wherein the placeholder includes a shaft section and a head section, wherein the head section is wider than the shaft section as measured along the common axis; and
a backside contact located on a backside surface of the first source/drain.

11. The microelectronic structure of claim 10, further comprising:
a backside interlayer dielectric layer located on a backside surface of the shaft section of the placeholder.

12. The microelectronic structure of claim 10, further comprising:
a shallow trench isolation liner located along a sidewall of the backside interlayer dielectric layer and located along a sidewall of the shaft section of the placeholder.

13. The microelectronic structure of claim 12, wherein the shallow trench isolation liner is in direct contact with a backside surface of the head section of the placeholder.

14. The microelectronic structure of claim 13, further comprising:
a shallow trench isolation fill layer located adjacent to and in direct contact with a sidewall of the backside contact.

15. The microelectronic structure of claim 14, wherein the shallow trench isolation liner is located between the shaft section of the placeholder and the shallow trench isolation fill layer.

16. The microelectronic structure of claim 15, wherein a sidewall of the head section of the placeholder is in contact with the shallow trench isolation fill layer.

17. The microelectronic structure of claim 10, wherein the head section and the shaft section of the placeholder gives the placeholder a bolt shaped profile as viewed along the common axis.

18. A method comprising:
forming alternating layers of sacrificial layers and nanosheet channel layers on a substrate;
separating the alternating layers into a plurality of rows, wherein the separating the alternating layers causes a plurality of trenches to form in the substrate;
lining the trenches with a shallow trench isolation liner and filling the remaining space within the trench with a shallow trench isolation fill layer; and
recessing the shallow trench isolation liner to create a sacrificial trench and forming a sacrificial plug in the sacrificial trench.

19. The method of claim 18, further comprising:
forming a source/drain region and forming a placeholder shaft trench between sections of the shallow trench isolation liner, wherein the sacrificial plug is aligned with the shallow trench isolation liner.

20. The method of claim 19, further comprising:
forming the head section of the placeholder trench by removing the sacrificial plug.
